(19) United States
(12) Patent Application Publication
(10) Pub. No.: US 2010/0292857 A1
(43) Pub. Date: Nov. 18, 2010

(54) ELECTRICAL NETWORK COMMAND AND CONTROL SYSTEM AND METHOD OF OPERATION

(75) Inventors: Sanjay Bose, Edison, NJ (US); A. Arthur Kressner, Westfield, NJ (US)

Correspondence Address: CANTOR COLBURN LLP, 20 Church Street, 22nd Floor, Hartford, CT, 06103, US

(73) Assignee: CONSOLIDATED EDISON COMPANY OF NEW YORK, INC., New York, NY (US)

(21) Appl. No.: 12/782,180

(22) Filed: May 18, 2010

Related U.S. Application Data
(60) Provisional application No. 61/179,168, filed on May 18, 2009.

(51) Int. Cl. G06F 1/28; G06G 7/63; G01R 21/00; G06F 19/00

(52) U.S. Cl. 700/292; 703/18; 702/62

(57) ABSTRACT

A system is provided that allows the aggregation of a plurality of inputs from an electrical grid and the display of the plurality of inputs on a single integrated display for a network operator. The system accepts signals from electrical loads and generation devices and analyzes the inputs to determine potential issues or trends, including fault predictions and recommends contingency plans. The system presents these potential issues and possible corrective actions to the network operator. The network operator may initiate actions, such as dispatching loads or activating generation capacity for example, in response.

### BACKGROUND OF THE INVENTION

The present invention relates generally to a system for managing an electrical network and more particularly to a system that aggregates, analyzes and assists the network operator in balancing electrical power generation and demand on the electrical networks.

The delivery of electrical power from a power generation plant to an end customer takes many routes. The electrical power is transmitted from the power generation plant to a high voltage transmission system that includes conductors and equipment for the transfer of the electrical power over long distances. Coupled to the transmission system at different locations are substations that transfer and transform the high voltage electrical power into a medium voltage distribution system. This medium voltage distribution system in turn delivers the electrical power to a low voltage distribution near the point of use (e.g. a residential neighborhood). This process involves many miles of conductors and hundreds of pieces of equipment that monitor, control and transform the electrical power.

Traditionally, the equipment used in the transfer of electrical power involved equipment having little or no remote monitoring or communications ability. The limited remote monitoring that was available was typically monitored by centralized control facilities that dispatched personnel to make adjustments and repairs as necessary. These control facilities managed discrete geographic areas and portions of the electrical grid. For example, a local control center may monitor and control a portion of the electrical grid in a city, while a regional control center would monitor and control the transmission to the local areas. It should be appreciated that between the generation and consumption of the electrical power, the electricity would be under the control of multiple control facilities at different times.

As consumers demand for electrical power has increased, automated equipment was installed to allow electric utilities to increase the efficiency of delivering electrical power to where it was needed the most. While the amount of remote monitoring increased, the control of the electrical grids remained fragmented with only limited ability to interact. So while efficiency and reliability increased, interoperability between different regions is limited since the electrical network is an aggregation of interconnected, but independent, electrical networks that were built at different time periods when the level of demand was lower.

To alleviate this problem an initiative called “SmartGrid” was started to utilize digital technology to allow the upgrading of transmission and distribution systems. One of the aims of SmartGrid is to incorporate remote communications, monitoring and control of equipment throughout the electrical grid from the transmission system down to appliances within a customers home. In this way, the grid operators can balance generation and demand while also increasing efficiency and reliability. However, the volume of data generated and the number of controllable devices as a result of this upgraded electrical grid poses challenges to the human operators who need to make decisions and execute commands in a timely fashion.

Thus, while existing electrical distribution systems are suitable for their intended purposes, there still remains a need for improvements particularly regarding the command and control of the electrical distribution network and the increased efficiencies that may be gained from utility electrical distribution networks.

### SUMMARY OF THE INVENTION

A system is provided that allows the aggregation of a plurality of inputs from an electrical grid and the display of the plurality of inputs on a single integrated display for a network operator. The system accepts signals from electrical loads and generation devices and analyzes the inputs to determine potential issues or trends, including fault predictions and recommends contingency plans. The system presents these potential issues and possible corrective actions to the network operator. The network operator may initiate actions, such as dispatching loads or activating generation capacity for example, in response.

### BRIEF DESCRIPTION OF THE DRAWINGS

Referring now to the drawings, which are meant to be exemplary and not limiting, and wherein like elements are numbered alike:

FIG. 1 is a schematic illustration of a utility electrical distribution system;

FIG. 2 is a schematic illustration of interconnections between a plurality of electrical distribution systems;

FIG. 3 is a schematic illustration of a portion of the utility electrical distribution system of FIG. 1; and,

FIG. 4 is a schematic illustration of a command and control system for the utility electrical distribution system of FIG. 1.

### DETAILED DESCRIPTION

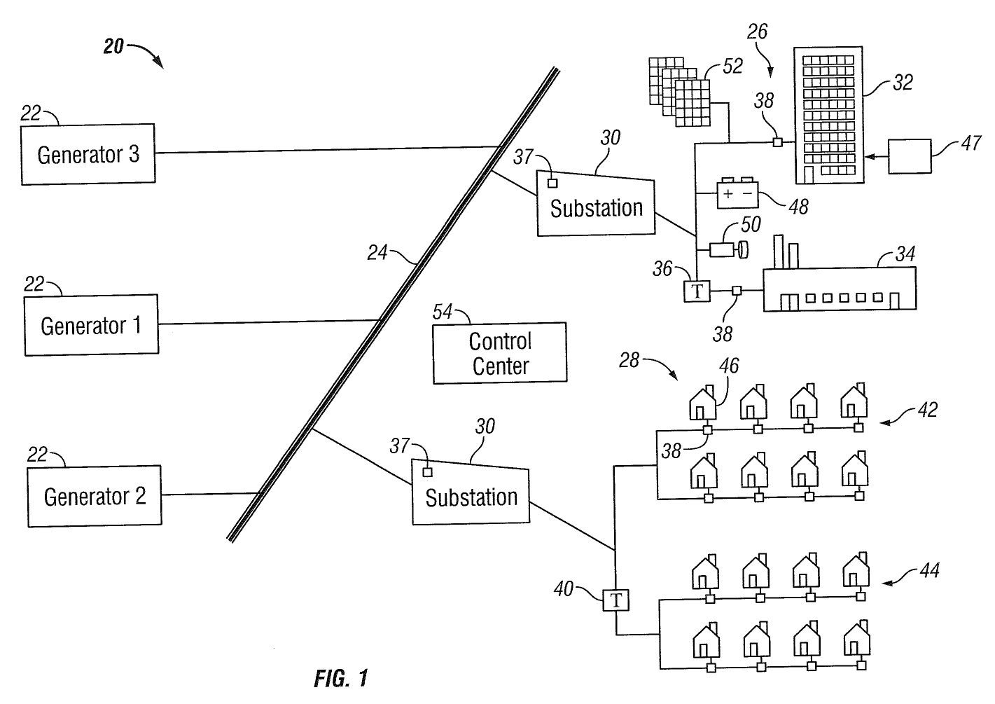

FIG. 1 illustrates an exemplary embodiment of a utility electrical distribution network 20. The utility network 20 includes one or more power plants 22 connected in parallel to a main transmission network 24. The power plants 22 may include, but are not limited to: coal, nuclear, natural gas, or incineration fueled power plants. Additionally, the power plants 22 may include one or more renewable hydroelectric, solar, or wind turbine power plants. It should be appreciated that additional components such as transformers, switchgear, fuses and the like (not shown) may be incorporated into the utility network 22 as needed to ensure the safe and efficient operation of the system. As discussed in more detail below, the utility network 20 may be interconnected with one or more other utility networks to allow the transfer of electrical power into or out of the electrical network 20.

The main transmission network 24 typically consists of high voltage or medium voltage power lines, and associated transmission equipment which carry the electrical power from the point of production at the power plants 22 to the end users located on local electrical distribution networks 26, 28. The local distribution networks 26, 28 are connected to the main transmission network by substations 30 which adapt the electrical characteristics of the electrical power to those needed by the end users. Substations 30 typically contain one or more transformers, switches, relays, fuses and other control equipment. Larger substations may also include circuit breakers to interrupt faults such as short circuits or over-load currents that may occur. Substations 30 may also include equipment such as fuses, surge protection, controls, meters, capacitors and voltage regulators. As will be discussed in more detail below, the transmission network and transmission network equipment include sensors and/or controllers 37 to allow electronic communication of electrical characteristics indicative of the operation of transmission network 24.

The substations 30 typically include multiple feeder circuits that connect the substation 30 to one or more local electrical distribution networks, such as local distribution network 26 for example, that provide electrical power to a commercial area having end users such as an office building 32 or a manufacturing facility 34 for example. Local distribution network 26 may also include one or more transformers 36 which further adapt the electrical characteristics of the delivered electricity to the needs of the end users. Substation 30 may also connect with other types of local distribution networks such as residential distribution network 28. The residential distribution network 28 may include one or more residential buildings 46 and also light industrial or commercial operations. A distribution network may also include multiple subnetworks 42, 44. These subnetworks 42, 44 may receive electrical power from one or multiple feeder circuits.

In the exemplary embodiment, the electrical loads such as residential buildings 46, office buildings 32, and manufacturing facilities 34 include one or more electrical meters 38. The electrical meter 38 typically includes a controller (not shown) that monitors the consumption of electrical power by the load and includes memory and communications circuits to allow electronic transmission of data, such as data representing the amount of consumed power and time of consumption for example, to the utility. This electrical meter 38 is sometimes referred to as an Advanced Metering Infrastructure or “AMI” meter. In other embodiments, the electrical loads 32,34, 46 include multiple meters that are associated with an individual load, such as an appliance for example. The meter 38 may include the ability to transmit and receive commands, instructions or data.

In addition to electrical loads, the distribution networks 26, 28 may also have local electrical generation capacity, sometimes referred to as distributed generation or “DG”. These DG units may generate and deliver electrical power directly to a load, such as a co-generation DG unit 46 that provides electrical power and heat to office building 32. The DG units may also generate and deliver electrical power to the distribution network. DG units may include energy storage devices, such as but are not limited to, advanced batteries 48, flywheel storage 50, and fuel cells. The DG units may also include generation devices, such as but not limited to photovoltaic solar panels 52, wind turbines, tidal generators, small natural gas turbines and the like. In some embodiments, the DG generation units may also include electrical power storage capability. It should be appreciated that typically individual DG units produce only a small portion of the electrical power needed by the distribution network. However, when operated collectively, the DG units may provide a significant amount of electrical power to ease the strains on the transmission and distribution networks, especially during periods of peak demand. It should also be appreciated that some DG units, such as solar or wind generation for example, may be affected by external factors, such as the weather for example.

In the exemplary embodiment, the DG units include a controller having memory and a communications circuit. The DG unit controller includes circuits for transmitting and receiving commands, instructions and data. In one embodiment, the DG unit controller may monitor, store and transmit data representative of operating conditions (e.g. speed, fuel, electrical power produced, electrical power stored, availability).

The utility network 20 may include one or more network control centers 54. The control center 54 operates the utility network to balance the generation of power by the power plants 22 and the DG units 47, 48, 50, 52 with the demand from electrical loads 32, 34, 46. It should be appreciated that except in limited circumstances, such as batteries 48 or flywheel storage device 50, electrical power cannot be stored and the generation needs to match the demand. As will be discussed in more detail below, the controller 37, meters 38 and sensors coupled to the utility network 20 provide data and receive instructions from the control center 54 to allow the network operator to maintain balanced conditions.

As discussed above, the utility network 20 may be connected with other utility networks 56, 58, 60. In one embodiment, the utility networks 20, 56, 58, 60 are each an Independent System Operator (ISO) or a Regional Transmission Organization (RTO). An ISO/RTO coordinates, controls and monitors the operation of the electrical power system in a geographic territory, such as one or more US States. Each ISO 20, 56, 58, 60 includes one or more interconnections 62 with neighboring electrical networks. In areas of deregulatized electrical production, the interconnections 62 allow the transfer of electrical power from independent power producers in one region to customers in other regions. These interconnections 62 are typically high voltage transmission systems. The interconnections 62 also include sensors and controllers arranged to measure the electrical characteristics of the interconnection 62. These sensors and controllers include memory and communications circuits for storing, transmitting and receiving commands, instructions and data, such as to or from control center 54 for example.

The interconnection of electrical networks, such as utility networks 56, 58, 60 are complex and create conditions that must be actively managed by the network operators. One such condition is known as a “loop flow.” Loop flows occur when the path over which power physically flows does not correspond to the path over which the power was scheduled to flow. For example, a power plant 22 in network 20 may desire to transfer electrical power to a customer in network 56. Due to a number of factors, such as lower transfer pricing for example, the power plant operator may desire to transfer the electrical power via network 60. However, since electricity flowing between a generator and a consumer travels via the path of least resistance, the electrical power produced by power plant 22 may be transferred via network 58. Loop flows are undesirable to network operators and utilities since they are difficult to predict and control. Loop flows may also create congestion on the network, especially at interconnections 62 that result in increased costs to network operators and their customers. In some instances, independent power producers and electrical power resellers have used the congestion caused by loop flows to obtain higher prices from the network operators.

Loop flows are complex and ordinarily occur as the result of a combination of factors, including: scheduling of energy transactions between the areas controlled by grid operators; scheduling electricity supply within each grid operator's system; demand for electricity within each grid operator's system; transmission outages; and generation outages. Loop flows occur in virtually all interconnected transmission systems. While loop flows cannot be eliminated, the network operators can manage and make adjusts as the loop flows typically follow general patterns. When the loop flow pattern changes (such as reversing), the network operators need to analyze the system to determine the cause. In cases where the change was due to market manipulation, the ISO's may cooperate with the Federal Energy Regulatory Commission (FERC) to enact regulations to prevent the manipulation. It should be appreciated that the detection of a market manipulation resulting in loop flow requires the analysis of large quantities of data from a broad geographic region.

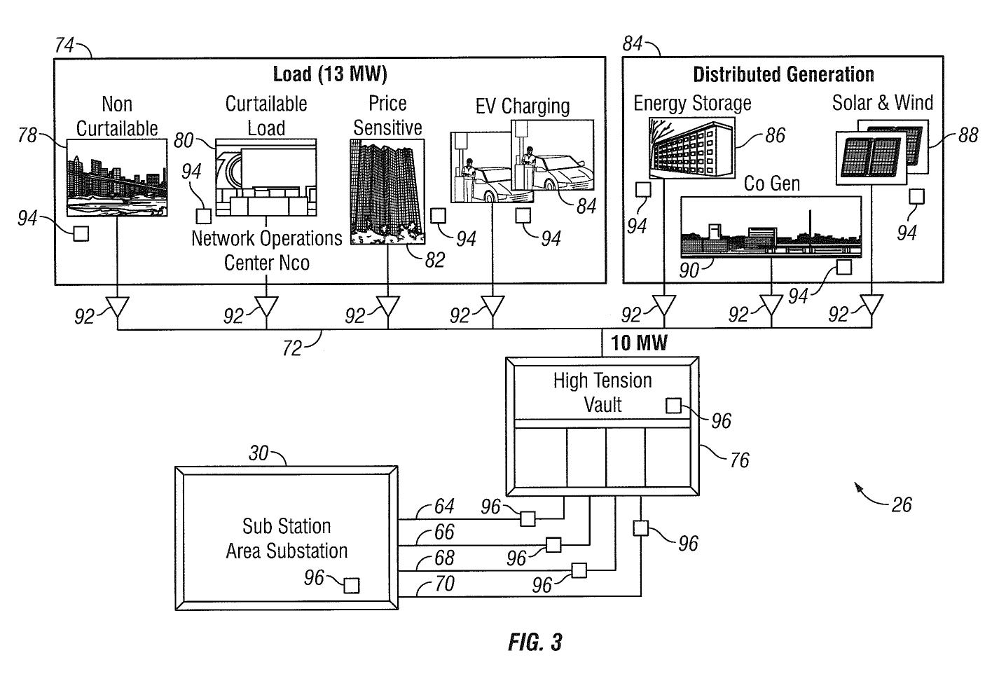

Referring now to FIG. 1 and FIG. 3, another embodiment of a local distribution network 26 is illustrated. This embodiment includes a substation 30 having four feeder circuits 64, 66, 68, 70 that transfer electrical power from the substation 30 to network portion 72 adjacent electrical loads 74. The four feeder circuits 64, 66, 68, 70 terminate at a high-tension vault 76. The high-tension vault 76 includes distribution equipment (not shown), such as transformers for example, as is known in the art. The high-tension vault 76 adapts the electrical power from the feeder circuits 64, 66, 68, 70 to the network portion 72. It should be appreciated that the distribution equipment housed in high tension vault 76 includes sensors and controllers with memory and communications circuits that allow instructions, commands and data to be received and transmitted, such as to/from the control center 54 (FIG. 1) for example.

The electrical loads 74 coupled to the network portion 72 may be comprised of a plurality of different types of loads. One type of load is referred to as a noncurtailable load 78. A noncurtailable load 78 sometimes referred to as a non-dispatchable load is one that has a high cost associated with interruption of electrical power. Examples of noncurtailable load 78 include high value facilities such as hospitals and tunnel lighting systems. Another type of load is referred to as a curtailable load 80. The curtailable load 80 includes loads that may be reduced or eliminated by the electrical utility to help balance demand with available generation. These curtailable loads 80 may be dispatched by the control center 54, either through an automated control system or through a voluntary system where requests are sent to the loads and the facility personnel reduce their loads. For example, one type of automated control system is a system that transmits a signal to a thermostat causing the set point of the thermostat to increase by several degrees. Curtailable loads 80 also include lighting in office buildings or residential hot water heaters for example.

A third type of load is a price sensitive load 82. A price sensitive load 82 is one that uses time-of-use billing in which financial incentives are given to the building or facility to curtail energy usage during peak periods. In some embodiments, the price sensitive load 82 may also participate in market bidding to increase the financial incentives. The fourth exemplary type of load is an electric vehicle (EV) charging station 84. As EV's grow in popularity there is an increasing demand for facilities to charge this vehicles when the operator is away from home. These charging stations 84 may be located near major office buildings or shopping malls for example. As a result, there is a growing load on electrical networks due to the charging of electrical vehicles.

Also coupled to the network portion 72 may be one or more distributed generation (DG) devices 84. These DG devices 84 provide small capacity electrical generation for local consumption. The availability of DG devices 84 reduces the amount of electrical demand that must be satisfied by the substation 30. Thus the DG devices 84 may be used by the control center 54 to assist in balancing the demand and the available generation from the power plants 22. One type of DG device 84 is an energy storage device 86 that absorbs electrical energy during off-peak time periods for later use. Another type of DG device 84 is a renewable energy source such as photovoltaic solar or wind turbines for example. Yet another type of DG device 84 is referred to as a cogeneration plant 90, which generates heat and electrical power for use by a facility. It should be appreciated that the DG devices 84 may also be directly associated with a load, such as curtailable load 80.

Each of the loads 74 and DG devices 84 include sensors 92 and/or controllers 94 that include processor, memory and communication circuits that allow the sensors 92 and/or controllers 94 to transmit, store and receive instructions, commands and data. In one embodiment, the distribution network 26 also includes sensors 96 that provide signals indicative of a electrical characteristics, such as current, voltage and phasor information. In one embodiment, one or more of the sensors 96 is a phasor measurement unit (PMU). A phasor is a complex number that represents both the magnitude and phase angle of the sine waves found in electricity. Phasor measurements that occur at the same time are called a “synchrophasors”, as are the PMU devices that allow their measurement. In typical applications, phasor measurement units are sampled from widely dispersed locations in the power system network and synchronized from the common time source of a global positioning system (GPS) radio clock. Synchrophasor technology provides a tool for system operators and planners to measure the state of the electrical system and manage power quality. Synchrophasors measure voltages and currents several times per second, at diverse locations on a power grid, and can output accurately time-stamped voltage and current phasors. Because these phasors are synchronized, synchronized comparison of two quantities is possible, in real time. These comparisons can be used to assess system conditions.

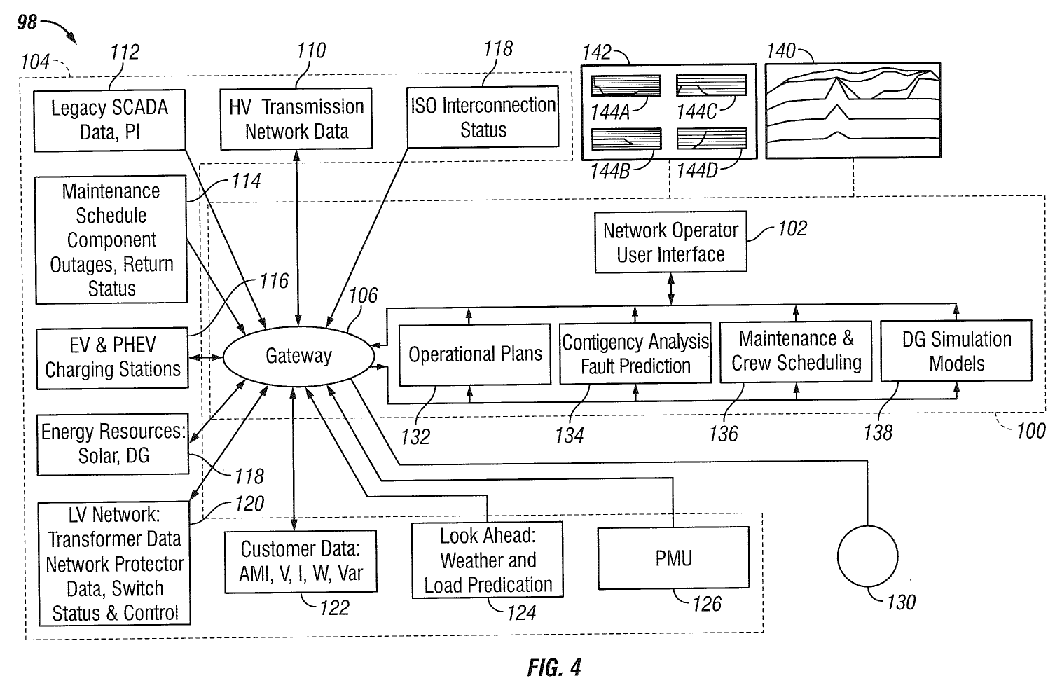

Referring now to FIG. 4, a command and control system 98 for aggregating data, displaying the data and providing analysis from the sensors and controllers discussed herein, above to allow the control center 54 to balance demand against generation capacity on a timely or real-time basis. The command and control system 98 includes a system 100, such as a computer server for example. The system 100 communicates with the plurality network controllers and sensors 104 described herein through a communications network. The communications network may be any type of known network including, but not limited to, a wide area network (WAN), a public switched telephone network (PSTN) a local area network (LAN), a global network (e.g. Internet), a virtual private network (VPN), and an intranet. The communications network may be implemented using a wireless network or any kind of physical network implementation known in the art.

In the exemplary embodiment, the system 100 may be implemented using one or more servers operating in response to a computer program stored in a storage medium accessible by a user interface server 102. The system 100 may operate as a network server (e.g., a web server) to communicate with the network controllers and sensors 104. The system 100 handles sending and receiving information to and from the network controllers and sensors 104 and can perform associated tasks. The system may also include firewalls or gateway 106 to prevent unauthorized access and enforce any limitations on authorized access. For instance, an administrator may have access to the entire system and have authority to modify portions of the system. A gateway 106 may be implemented using conventional hardware and/or software as is known in the art.

In the exemplary embodiment, the gateway 106 provides a secure communication channel to the controllers and sensors 104. This secure communications channel complies with cybersecurity standards to prevent intrusion, interception or manipulation of data transmitted between the controllers and sensors 104 and the gateway 106. In one embodiment, the gateway 106 includes the ability to transmit and receive data from mobile devices 130, such as cellular phones for example, to notify customers of alerts or opportunities related to their electrical usage. It should be appreciated that while a single gateway 106 is illustrated herein, this is for purposes of clarity and the gateway 106 may also comprise several devices or modules.

In the exemplary embodiment, the controllers and sensors 104 include, but are not limited to an ISO interconnection status module 108; a transmission network data module 110; legacy supervisory control and data acquisition (SCADA) data module 112; maintenance schedule module, components outages and return status data module 114; EV charging station module 116; DG energy resources module 118; low voltage network equipment module 120; customer meter data module 122; weather and load prediction data module 124; and PMU data module 126. These modules 108-126 may incorporate machine learning and pattern recognition algorithms to assist in analysis of data, such as that described in co-pending, commonly assigned U.S. patent application Ser. No. 12/178,553 by Arthur Kressner, Mark Mastrocinque, Matthew Koenig and John Johnson which is incorporated by reference in its entirety. These modules 108-126 may further incorporate rules based decision logic, such as business operation rules and safety rules and associated support algorithms to assist the electrical network operator.

The gateway 106 receives data and transmits data and commands. In the exemplary embodiment, the system 100 includes a plurality of modules such as operational plans module 132, contingency analysis and fault prediction module 134, maintenance and crew-scheduling module 136, and DG simulations module 138. Each of the modules 132, 134, 136, 138 is capable of receiving a plurality of inputs and providing outputs. The outputs may be transmitted to the User Interface 102 or to the controllers and sensors 104. Similarly, the inputs may be received from the user interface 102 or the controllers and sensors 104. It should be appreciated that as used herein, the term “modules” or “systems” may be implemented in a variety of forms including hardware, firmware, software or any combination thereof.

In the exemplary embodiment, the user interface 102 receives data from the modules 132, 134, 136, 138 and the gateway 106 and transforms the data into a visual representation on a display, as such the user interface 102 may include an LED (light-emitting diode) display, an LCD (liquid-crystal diode) display, a CRT (cathode ray tube) display, or the like. A keypad may also be coupled to the user interface 102 for providing data input to the system 100.

In one embodiment, the user interface transforms physical data of the utility network 20 (FIG. 1) in a visual display. The visual display may be a window 140, illustrating a graphical representation of a metric indicating a status of the utility network 20, such as in the form of a stacked line graph for example. The metric may be the amount of electrical power being contributed to a section of the network, such as network portion 72 for example. In one embodiment, the amounted of contributed electrical power is displayed as a percentage of the total amount of electrical power being transmitted to the section of the network. The use of a window 140 having a graphical representation allows the network operator to quickly ascertain the current condition of the electrical network. For example, in the embodiment where the window 140 is displaying the conditions of network portion 72, if the operator sees that one of the feeders 64, 66, 68, 70 is operating at a higher power level, this may indicate a problem on the network portion 72 or with one of the other feeder circuits. Left unabated, the feeder circuit operating at the higher power level may fail resulting in the load being shifted to the other feeder circuits. The user interface 102 allows the network operators to further interrogate the operating conditions on the network portion 72 to ascertain the reason the one feeder circuit is operating at a higher power level than the other circuits.

In one embodiment, the system 100 includes a rule-based engine, such as in contingency analysis and fault prediction module 134 for example, that analyzes the data and transmits to the network operator potential faults that may occur. The contingency analysis and fault prediction module 134 may also analyze the current conditions and provide a list of corrective actions to improve the balance or alleviate issues within the electrical network. In one embodiment, the operational plans module 132 defines the corrective actions. In another embodiment, the DG simulation module 138 analyzes the corrective actions. In yet another embodiment, once the network operator selects one or more corrective actions, the maintenance and crew scheduling module 136 dispatches personnel, such as by automatically communicating a signal to mobile devices 130 via gateway 106 for example. The user interface 102 may include other displays, such as a window 142 having multiple viewports 144A, 144B, 144C and 144D for example.

In the exemplary embodiment, the system 100 may also receive data from the controllers and sensors 104 and provide alerts to the network operator. For example, the system 100 may receive data regarding weather predictions from weather and load prediction data module 124. For example, the weather and load prediction data module 124 may indicate that the weather will be clear and sunny later in the day. The weather prediction data is analyzed by DG simulation module 138 which then transfers an output data representing the operation of the DG device, such as photovoltaic solar device 52 (FIG. 1) for example, into the contingency analysis and fault prediction module 134. Since the weather will be clear, a solar-based DG device (e.g. solar device 52) will produce a larger amount of electrical power. The data is then presented to the network operator who can chose to use the increased output from solar based DG devices and reduce the power flowing through one of the feeder circuits. Similarly, if weather and load prediction data module 124 indicated cloudy weather, the DG simulation module 138 and contingency analysis and fault prediction module 134 could provide the network operator with data showing the impact of the weather and allow the network operator to initiate actions to offset the loss in electrical power, such as by dispatching curtailable loads or purchasing additional electrical power from a power plant.

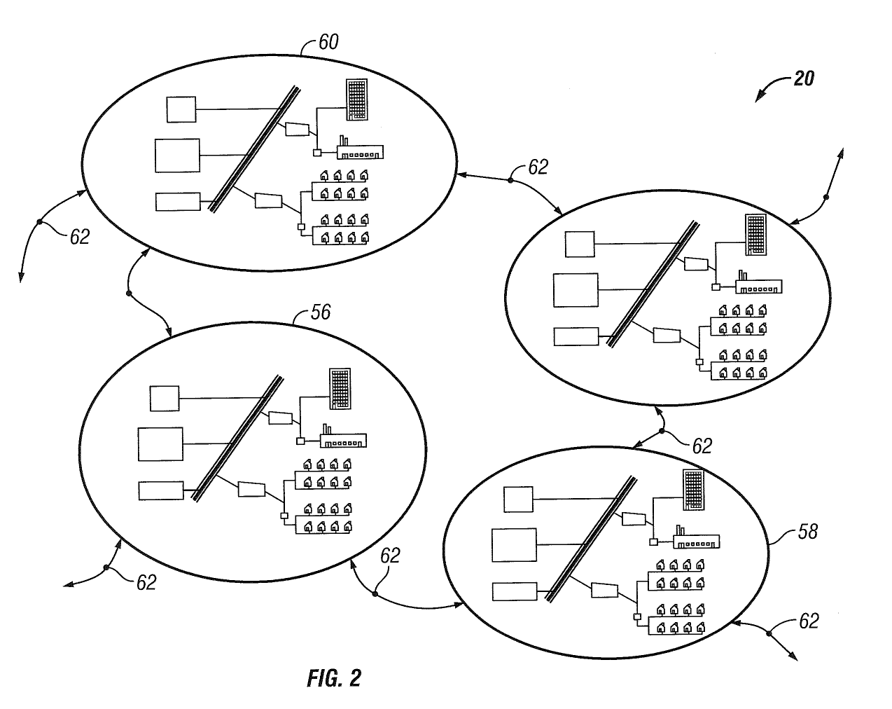

In another embodiment, the command and control system 98 is a control system for an ISO or RTO. In this embodiment, the system 100 may receive data related to the interconnections 62 (FIG. 2) with other adjoining ISO/RTO regions. The system 100 may also receive data from PMU's 126 providing virtually real-time operating conditions on the ISO network. As such, the system 100 can notify the network operator of flow loops that may be occurring within the ISO network, perform simulations and present corrective actions. The system 100 may also be able to record trends in the flow loops and be able to identify reversals in trends that may indicate a market manipulation.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. A system for an electrical network comprising:
a control center having at least one display and a user interface;
a plurality of load devices coupled to said electrical network, each of said plurality of load devices including a first sensor for monitoring said electrical network and a first communications circuit coupled to communicate with said control center;
a plurality of generation devices coupled to said electrical network, each of said plurality of generation devices including a second sensor for monitoring generation characteristics of each of said plurality of generation devices and a second communications circuit coupled to communicate with said control center; and,
wherein said control center includes at least one processor, said at least one processor being responsive to receive a first signal from said plurality of load devices and said plurality of generation devices and providing an output to said at least one display, wherein said output provides a network operator with a characteristic metric of said electrical network.

2. The system of claim 1 wherein said at least one processor is further responsive to a first input from said user interface and transmitting a second signal to at least one of said plurality of load devices in response to said first input.

3. The system of claim 2 wherein said at least one processor is further responsive to a second input from said user interface and transmit a third signal to at least one of said plurality of generation devices in response to said second input.

4. The system of claim 3 further comprising a weather monitoring device coupled to communicate with said control center.

5. The system of claim 4 wherein said at least one processor determines a predicted generation characteristic in response to a fourth signal from said weather monitoring device.

6. The system of claim 2 wherein said at least one of said plurality of load devices a curtailable load.

7. The system of claim 3 wherein at least one of said plurality of generation devices is an energy storage device.

8. A command and control system comprising:
a server having a processor and a display;
a gateway coupled to communicate with said server;
a plurality of network controllers and sensors coupled to communicate with said server via said gateway;
wherein said processor is responsive to executable instructions when executed on said processor for displaying a graphical representation of a metric on said display indicating a status of a utility network in response to data received from said plurality of network controllers and sensors;
wherein said processor is further responsive to executable computer instructions for executing a contingency analysis and fault prediction module and displays potential faults and a plurality of corrective actions on said display.

9. The system of claim 8 wherein said plurality of network controllers and sensors includes at least of an ISO interconnection status module, a transmission network module, a SCADA data module, a maintenance schedule module, and a component outage and return status data module.

10. The system of claim 8 wherein said plurality of network controllers and sensors includes at least of an electric vehicle charging station module, a distributed generation resources module, a low voltage network equipment module, a customer meter data module, a weather and load prediction data module, and a phasor measurement unit data module.

11. The system of claim 8 wherein said graphical representation of said metric is a representative of an amount of electrical power being contributed to a section an electrical network.

12. The system of claim 11 wherein said graphical representation of said metric includes a plurality of power levels each of said plurality of power levels being associated with a feeder circuit.

13. The system of claim 8 wherein said processor is further responsive to executable computer instructions for executing a operational plans module to generate said plurality of corrective actions.

14. The system of claim 8 said processor is further responsive to executable computer instructions for executing a maintenance and crew scheduling module in response to an input selecting one of said plurality of corrective actions.

15. The system of claim 14 wherein said processor transmits a signal to a mobile device via said gateway in response to said input.

16. A method of operating an electrical distribution network comprising:
receiving a plurality of signals from a plurality of network controllers and sensors via a gateway;
determining at least one network metric from said plurality of signals;
displaying said at least one network metric;
determining a potential network fault from said plurality of signals;
providing a plurality of corrective actions to alleviate said potential network fault;
displaying said plurality of corrective actions;
automatically transmitting a first signal to a mobile device in response to a selection of one of said plurality of corrective actions.

17. The method of claim 16 further comprising:
determining a weather prediction data;
determining a distributed generation device output data in response to said weather prediction data; and,
displaying said distributed generation device output data.

18. The method of claim 17 further comprising transmitting a second signal to a curtailable load in response to said distributed generation device output data.

19. The method of claim 18 further comprising displaying said distributed generation device output data as percentage of electrical power of a section of said electrical distribution network.
